(19) United States
(12) Patent Application Publication
(10) Pub. No.: US 2011/0011157 A1
(43) Pub. Date: Jan. 20, 2011

(54) GAS CHROMATOGRAPH COLUMN WITH CARBON NANOTUBE-BEARING CHANNEL

(76) Inventors: Bertrand Bourlon, La Colle Sur Loup (FR); Joyce Wong, Pasadena, CA (US); Paul B. Guieze, Fontennailles (FR)

Correspondence Address: SCHLUMBERGER OILFIELD SERVICES, 200 GILLINGHAM LANE, MD 200-9, SUGAR LAND, TX, 77478, US

(21) Appl. No.: 12/503,902

(22) Filed: Jul. 16, 2009

(51) Int. Cl. G01N 30/04; E21B 47/08; G03F 7/20

(52) U.S. Cl. 73/23.41; 73/152.55; 430/320

(57) ABSTRACT

A carbon nanostructured micro-fabricated gas chromatography column which is particularly well-suited to the surface well-site and/or the downhole analysis of natural gas in oilfield or gasfield applications (but which may also be used in non-oilfield or non-gasfield situations) is described. This micro-fabricated column integrates a micro-structured substrate such as a silicon substrate with carbon nanotubes as an active nanostructured material in a micro-channel. Benefits of the present invention include enhanced separation of alkanes and isomers, particularly below hexane (i.e., below C₆), as well as the separation of carbon dioxide, hydrogen sulfide, and water and other substances present in natural gas. The chromatography column of the present invention is in one embodiment a part of an entire gas chromatograph system that in its simplest form also comprises an injector and a detector. Preferably the injector, separation column, and detector are all micro-fabricated on a substrate.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND

1. Technical Field

The present disclosure relates generally to the field of gas chromatography, and more particularly, but not by way of limitation, to methods of micro-fabricating gas chromatography separation columns and use of such components in the gas chromatographic analysis of natural gas.

2. Background Art

Gas chromatography (GC) has been used for more than 50 years within the field of natural gas analysis to separate and quantify the different components/analytes/molecules found within natural gas. Gas chromatographs separate mixtures of gases by virtue of the different retention of their various components on a stationary phase of a separation column. During much of this time period, the technology used within gas chromatographs has generally remained the same. For example, the equipment used for gas chromatographs within laboratories has remained fairly large and cumbersome, thereby limiting the adaptability and versatility for the equipment. These limitations may be a strain on resources, as moving the equipment around may be a challenge that requires an unnecessary amount of time and assets. Because of the bulkiness of the existing GC analyzers for gas analysis this analysis is typically performed off-line/off-site in a laboratory environment. However, within about the past 10 years, certain efforts have been made in reducing the size of GC gas analyzers mainly in applications other than natural gas.

An example of a miniaturized gas chromatograph is disclosed in U.S. Published patent application No. 2006/0210441 A1 to Schmidt (“Schmidt”). This application describes a GC gas analyzer that includes an injector, a separation column, and a detector all combined onto a circuit board (such as a printed circuit board). The injector then incorporates a type of slide valve, which is used to introduce a defined volume of liquid or gas. Schmidt asserts that by using this slide valve, the gas chromatograph may create a reliable and reproducible gas sample. This gas sample is then injected into the column to separate the gas sample into various components.

Though Schmidt describes a smaller gas chromatograph for manufacturing, such chromatographs have still been slow to develop for use within the natural gas industry. For example, there are some gas chromatographs that are manufactured commercially for use within the natural gas industry, but these chromatographs are designed specifically for analyzing particular types of natural gas which may comprise only a small portion of the entire spectrum of types of natural gas. Such gas chromatographs are therefore not useful or applicable outside of this narrow application. For example, natural gases that are found within hydrocarbon fields may vary from having only a trace of carbon dioxide to having over 90% carbon dioxide and may comprise various percentages of C1-C6 alkanes. This large variation within the ranges of the components of natural gas makes it difficult for gas chromatographs to correctly separate and analyze the components within the natural gas.

Recently new solutions have been proposed that consist of replacing the lab instrument by an online small sensor. This has now become possible thanks to advances in Micro-Electro-Mechanical-System (MEMS) technologies that enable the building of reproducible devices at the micro-scale.

An example of a miniaturized gas chromatograph which is particularly designed for use in the oil and natural gas industry is taught by European Patent publication No. 2 065 703 A1 to Guieze (“Guieze”). Guieze teaches a natural gas analyzer which can be disposed on a microchip (such as a silicon microchip) and includes an injector block and at least a first and second column block each of which has a separation column and a detector. The injector block includes a first input to receive composite gas, a second input to receive carrier-gas, and an output to expel the received composite gas and carrier-gas as a gas sample. Each separation column has an input to receive the gas sample, a stationary phase to separate the gas sample into components, and an output to expel the components of the gas sample from the stationary phase. The detector is then arranged to receive the components of the gas sample from the output of the separation column. Further, the injector block and the first and second column blocks are arranged in series on an analytical path of the microchip such that the gas sample expelled by the output of the injector block is received within the first column block. The gas sample is then separated into a resolved component and an unresolved component, in which the unresolved component is expelled by the first column block and received within the second column block. In the method of use of the gas analyzer, the method includes sampling a volume of natural gas with a sampling loop of an injector block to create a gas sample. The gas sample is then injected from the injector block to a first column block using a carrier gas from a reference path. Further, the gas sample may be separated into an unresolved component and a resolved component using a separation column of the first column block.

Standard methods exist for fabricating various MEMS components such as micro-valves and channels in microchips. For example, silicon wafers may be coated with a photoresist material and a desired valve and/or channel pattern may be etched into the wafer using a technique such as Deep Reactive Ion Etching (DRIE). In the case of the fabrication of a MEMS gas chromatography sensor, one of the key components is the fabrication of the micro-column and the stationary phase therein.

More generally speaking, the separation functionality of gas chromatography columns is enabled by a stationary phase or packing material that coats the inner walls or fills the space inside the column. In the case of natural gas analysis, the stationary phase usually has been based on polydimethylsiloxane (PDMS). Some examples of conventional packing materials used as a solid stationary phase are molecular sieves, carbon based materials (“Carbopack”) and porous polymer materials (“Porapak,” “HayeSep”). Traditionally, these materials have been used to coat or fill macroscopic tubes and capillaries. While there has been an interest from the application and performance standpoint to replace tubes and capillaries with micro-fabricated channels, one of the main issues has been to find a reliable and controlled process to coat or fill uniformly those micro-channels or structures with an appropriate stationary phase or packing material. Indeed the width of the micro-channels can be as low as few tens of microns. Moreover, the uniformity of the stationary material in the channel (i.e., the uniformity of the thickness of the stationary material in the channel) is usually critical for optimal performance of a chromatographic column.

Carbon nanotubes (CNTs) were discovered in 1991, and since then they have been intensively studied as an ideal object for research in Nanosciences and Nanotechnologies. Because of their size and their atomically well defined geometry, CNTs are excellent building blocks at the nanoscale. They are fibrils of pure graphitic carbon with nanometer diameters and typical lengths from microns to centimeters. Two main families of CNTs are usually defined: single-walled and multi-walled carbon nanotubes. A single-walled carbon nanotube (SWNT) can be seen as a single atomic layer thick sheet of graphite rolled into a cylinder. A double-walled carbon nanotube (DWNT) or multi-walled carbon nanotube (MWNT) consists of two to several concentric graphene layers, respectively, parallel to the nanotube axis (see for example U.S. Published Patent Application 2008/0176052). CNTs (especially SWNTs) have very high surface area to volume ratios, and are also resistant to high temperatures and chemicals. Adsorption of gas molecules on their surfaces as well as trapping of small molecules in atomic scale cavities created by defects has been demonstrated. Those last properties make CNTs a very interesting material for consideration as a stationary phase or packing material for gas chromatography applications. Moreover, over the last decade, it is possible to grow CNTs from a thin metallic film using chemical vapor deposition. While it is not yet possible to have full control of the nanotube chiralities, it is currently possible to have some control on the diameter, length and density of CNTs.

CNTs have previously been used in chromatographic systems as a stationary phase in the separation column. For example, the use of MWNTs as a stationary phase for chromatography has been disclosed in Li and Yuan (2003), Kartsova and Makarov (2004), Saridara and Mitra (2005), Ma et al. (U.S. Published Patent Application 2008/0017052), Lu et al. (U.S. Published Patent Application 2006/0231494), Boyle et al. (U.S. Published Patent Application 2007/0084346), and Mitra and Karwa (U.S. Published Patent Application 2008/0175785). The use of SWNTs as a stationary phase for chromatography has been disclosed in Karwa and Mitra (2006) and Yuan et al. (2006).

More particularly, Stadermann et al. (2006), Fonverne et al. (2008), Reid et al. (2009), Ricol et al. (Published PCT Application WO2006/0122697), and Fonverne et al. (U.S. Published Patent Application 2009/0084496) have disclosed the in situ growth of SWNTs and/or MWNTs on the inner surfaces of micro-channels fabricated on microchips for use in miniaturized integrated analytical tools known as micro-total analysis system (μ-TAS) or “Lab-on-a-chip”.

As noted above, the use of a MEMS gas chromatograph as a component of a natural gas analyzer on a microchip for use downhole in the wellbores of oil and gas wells has been contemplated by Guieze (EP 2 065 703 A1). Other examples of the architecture of self-contained micro-scale MEMS gas chromatographs which are constructed for downhole applications have been described in Shah et al. (U.S. Published Patent Application 2008/0121016) and Shah et al. (U.S. Published Patent Application 2008/0121017).

However, in spite of the progress described above which has been made in the development of micro-scale gas analyzing, MEMS devices which can be used downhole in oil and gas wells, progress in the development of improved stationary phases to be used in the separation columns of the micro-scale gas chromatography devices, and separation of analytes having molecular masses lower than hexane at a high resolution has lagged behind. It is to rectifying these and other shortcomings of the current technology that the methods and apparatus of the present invention is directed.

### SUMMARY OF THE DISCLOSURE

In view of the foregoing disadvantages, problems, and insufficiencies inherent in the known types of methods, systems and apparatus present in the prior art, exemplary implementations of the present disclosure are directed to apparatus, methods and systems which provide a new and useful micro-scale gas chromatography separation capability which avoids many of the defects, disadvantages and shortcomings of the prior art mentioned heretofore, and includes many novel features which are not anticipated, rendered obvious, suggested, or even implied by any of the prior art devices or methods, either alone or in any combination thereof.

More particularly, the present invention describes a carbon nanostructured micro-fabricated gas chromatography column, and a micro-fabricated gas chromatograph device comprising said column, which is particularly well-suited to the analysis of natural gas in oilfield or gasfield applications (but which may also be used in non-oilfield or non-gasfield situations). The process for making the column is an alternative solution to other stationary phases or packing materials generally used in separation columns for natural gas analysis. This micro-fabricated column integrates a micro-structured substrate, such as a silicon substrate, with carbon nanotubes as an active nanostructured material comprising the stationary material of the column. The fact that CNTs are chemically resistant, high temperature resistant materials with unusual physicochemical properties have been found herein to make them an excellent choice for use in the harsh environments of gas or oil wells. MEMS columns fabricated with this process have been realized herein, with advantageous properties demonstrated for natural gas analysis. The particular benefits of the present invention include enhanced separation of alkanes (including isomers) below hexane (i.e., below C₆), as well as the separation of nitrogen, oxygen, carbon dioxide, hydrogen sulfide, and water and other substances present in natural gas.

The chromatography column of the present invention is in one embodiment a part of a completely micro-fabricated gas chromatograph, which in its simplest form also comprises an injector and a detector. The injector is used to inject a small defined volume of the gas to be analyzed. This small volume of gas is carried by a mobile gas phase through the separation column where the different analytes are separated and passed to the detector. The detector senses the different analytes exiting the column. The final data is a chromatogram that is a graph (or other digitized representation of the data) in which the different analytes are seen as detected peaks as a function of time. From the chromatogram, it is possible to quantify the composition of each analyte constituting the analyzed gas.

The micro-fabricated column contemplated herein is mainly a functionalized or coated microfluidic channel or plurality of channels etched in silicon (or other suitable material) and sealed with a glass slide or other material appropriate for bonding. The microfluidic channel is connected to an injector at the inlet and a detector at the outlet. The channel itself can be hollow or include other micro-fabricated structures or pillars which increase the surface area within the channel. Typical column length ranges from, but is not limited to, a few centimeters to a few meters. Column height and width can vary, typically, from, but is not limited to, a few tens to a few hundreds of microns.

Preferably, all surfaces of the inner walls (including the side walls and bottom surface) of the channel or channels of the column (with or without additional micro-structures or pillars) are covered with an in situ generated CNT mat. These CNTs can be SWNTs, DWNTs, MWNTs, or BCNTs, or mixtures of each, in aligned or entangled bundles. These CNTs typically (although are not limited to) have a diameter of from less than one nm to a few nm, to a few tens of nm, to a few hundreds of nm, and a length from a few tens of nm to a few hundreds of nm to a few microns, to tens of microns.

This nanostructured material is preferably substantially uniformly deposited (as described in more detail below) along the length of and inside the micro-channels of the micro-column using a process compatible with large scale wafer-level production at industrial facilities. This process has an added flexibility in that it can be carried out inside a closed micro-channel or on the surfaces of an open micro-channel which can be closed subsequently by various bonding techniques without the need for substrate alignment. Moreover, the process from beginning to end can be kept completely dry, avoiding any degradation of the nanostructured stationary phase. The CNT mats are preferably grown by a chemical vapor deposition (CVD) process from a catalyst deposited on the exposed surfaces (walls and bottoms) of the micro-channel. The catalyst in one embodiment comprises a thin metallic layer deposited by sputtering. The choice of experimental parameters such as temperature, duration, gases used during the CVD process, or the metal compounds and thickness sputtered is important in the fabrication of an efficient CNT stationary phase.

According to an aspect of the present disclosure, the present invention is directed to a method for micro-fabricating a carbon nanostructured gas chromatography channel, comprising the steps of: providing a substrate; preparing and etching a surface of the substrate to form an etched substrate having a fluid channel, assembling a mat of carbon nanotubes on a wall surface of the fluid channel, wherein the mat of carbon nanotubes is substantially uniform in thickness along the length of the fluid channel, and the formation of contaminates on the surface of the etched substrate is minimized, and disposing a cover over at least a portion of the surface of the etched substrate for enclosing at least a portion of the fluid channel. The step of preparing and etching may further comprise applying a photoresist material upon the surface of the substrate, removing a portion of the photoresist material using photolithography, and etching the fluid channel in the substrate using a deep reactive ion etching process. Further, the step of assembling the mat of carbon nanotubes may comprise exposing the etched substrate to a metal or metal precursor to form a metal catalyst layer thereon, wherein at least a portion of the metal catalyst layer is formed upon the wall surface of the fluid channel, and exposing the metal catalyst layer to a carbon-containing gas at a temperature suitable for formation of carbon nanotubes on the wall surface of the fluid channel. Further, in the step of exposing the etched substrate to a metal or metal precursor to form the metal catalyst layer thereon, the metal or metal precursor may comprise at least one of a Group VIII, Group Vb, Group VIb, Group VII, or lanthanide metal, or an alloy comprising an additional metal. Also, the substrate used in the method may comprise silicon, sapphire, gallium arsenide, a Group III-IV material, and be doped or undoped, for example. Further, the carbon nanotubes may comprise single-walled carbon nanotubes and/or multi-walled carbon nanotubes. At least a portion of the fluid channel is preferably enclosed using a Pyrex glass wafer and/or silicon. And, optimally, the step of assembling the carbon nanotubes occurs in a manner to reduce formation of amorphous carbon on the surface of the etched substrate.

In another aspect of the present disclosure, the invention is directed to a micro-scale gas chromatograph for separating components of natural gas, comprising an injector block for providing a gas sample for separation into a plurality of components, a separation column for receiving the gas sample, the separation column having an input to receive the gas sample, a stationary phase comprised of carbon nanotubes grown upon a metal catalytic layer disposed upon a micro-channel in the separation column in a substantially uniform layer along the length of the micro-channel, and an output through which is expelled the components of the gas sample, and a detector arranged to receive the components of the gas sample from the output of the separation column. The separation column is etched into a substrate which may be silicon-based. The separation column preferably has a micro-channel length of at least 0.5 m. The micro-scale gas chromatograph is preferably adapted for use on-site at or near a wellhead of a wellbore.

In another aspect of the present disclosure, the invention is directed to a method for analyzing a gas sample (preferably a natural gas sample) comprising a plurality of analytes having molecular masses lower than hexane. The method includes the steps of providing a micro-scale gas chromatograph such as describe above, injecting the gas sample into the micro-scale gas chromatograph wherein at least a portion of the plurality of analytes are separated by the carbon nanotubes in the separation column of the micro-scale gas chromatograph, and detecting the portion of the plurality of analytes separated by the separation column as a function of time. Preferably the portion of the plurality of analytes separated by the separation column comprises at least two of methane, ethane, a propane, a butane, a pentane, carbon dioxide, and hydrogen sulfide. The gas sample may be analyzed at a surface by positioning the micro-scale gas chromatograph in fluid communication with a sampling apparatus and/or a separator apparatus wherein the gas sample is obtained from the fluid formation adjacent the wellbore. Or, the gas sample may be analyzed downhole by disposing the micro-scale gas chromatograph within a wellbore and the gas sample is obtained from a fluid formation adjacent the wellbore. Preferably, the analytes separated in the separation column are separated by a resolution factor R>1.5. Further, the CNTs of the separation column may be heated by passing an electric current through the metal catalyst layer of the micro-scale gas chromatograph.

In another aspect, the present disclosure is directed to a downhole tool for analyzing a fluid sample in a wellbore, the downhole tool comprising a housing operatively connected to a conveyable line, a micro-scale gas chromatograph as described above which is positioned in the housing, and a communication link providing an operative communication between the micro-scale gas chromatograph of the downhole tool and a power assembly. The downhole tool may be a drilling tool, a wireline tool, a tool string, a bottom hole assembly, or a well survey apparatus.

These together with other aspects, features, and advantages of the present disclosure, along with the various features of novelty, which characterize the invention, are pointed out with particularity in the claims annexed to and forming a part of this disclosure. The above aspects and advantages are neither exhaustive nor individually or jointly critical to the spirit or practice of the disclosure. Other aspects, features, and advantages of the present disclosure will become readily apparent to those skilled in the art from the following description of exemplary embodiments and description in combination with the accompanying drawings. Accordingly, the drawings and description are to be regarded as illustrative in nature, and not restrictive.

### BRIEF DESCRIPTION OF THE DRAWINGS

Various aspects and embodiments of the invention are described below in the appended drawings to assist those of ordinary skill in the relevant art in making and using the subject matter hereof. In reference to the appended drawings, which are not intended to be drawn to scale, like reference numerals are intended to refer to identical or similar elements. For purposes of clarity, not every component may be labeled in every drawing.

FIG. 1A is a schematic representation in cross-section of a wellhead sampling unit and gas chromatograph system of the present invention in an exemplary operating environment.

FIG. 1B is a schematic representation of one embodiment of a sampling unit and gas chromatograph system for downhole analysis of formation fluids according to the present invention with an exemplary borehole tool deployed in a wellbore.

FIG. 2 is a perspective view of components of a micro-fabricated gas chromatography apparatus according to an embodiment of the invention.

FIG. 3 represents a cross-sectional schematic view of a process of fabrication of a carbon nanotube (CNT) coated column on a wafer, (A) deposition on the wafer of a photoresist material by spincoating, (B) photolithography and etching of channels by DRIE, (C) sputtering of the metallic catalyst on the channel and remaining photoresist material, (D) lift-off of the remaining photoresist material and metal catalyst deposited on the photoresist material, (E) CNT growth of the metal catalyst layer on the channels of the column by CVD, (F) silicon-pyrex anodic bonding to seal the CNT-coated channels.

FIG. 4 represents a time/temperature cycle for chemical vapor deposition (CVD) and growth of CNTs on the metal catalyst lining the column channels of FIG. 3. Ar, H₂, and C₂H₄ represent argon, hydrogen, and ethylene gases supplied before, during, and after CVD.

FIG. 5 are SEM photomicrographs of the micro-fabricated column micro-channels coated with CNTs, (A) general top plan view of part of a micro-fabricated column, (B) side view of micro-channel wall coated with nanotubes, (C) cross-sectional view of micro-fabricated micro-channels. CNTs coat the vertical walls and bottom of the micro-channel.

FIG. 6 shows SEM photomicrographs of the micro-channels of the micro-fabricated column including pillar structures coated with carbon nanotubes, (A) general top plan view of part of the micro-fabricated column, (B) top plan view of a micro-channel containing micro-pillars, (C) enlarged view showing carbon nanotubes grown on a silicon micro-pillar, (D) cross-sectional perspective view inside a micro-channel showing three pillars. CNTs coat the walls and bottoms of the pillar micro-structures.

FIG. 7 is a photograph of a CNT-coated micro-fabricated column of the present invention. The total size is several cm².

FIG. 8 is a chromatogram of the separation of an O₂/N₂—CH₄—CO₂ mixture using a CNT-coated micro-fabricated column of the present invention.

FIG. 9 is a chromatogram of the separation of an air-propane-isobutane mixture using a CNT-coated micro-fabricated column of the present invention.

FIG. 10 is a block diagram illustrating one embodiment of a gas chromatography system according to the present invention.

FIG. 11A is a block diagram of one example of component layout for a gas chromatography apparatus according to aspects of the present invention.

FIG. 11B is a block diagram of another example of component layout for a gas chromatography apparatus according to aspects of the present invention.

FIG. 11C is a block diagram of another example of component layout for a gas chromatography apparatus according to aspects of the present invention.

FIG. 12 is a block diagram of another embodiment of a gas chromatography system according to the present invention.

FIG. 13 is a top view of a geometry of one embodiment of a gas chromatography column according to an embodiment of the present invention.

FIG. 14 is a cross-sectional view of the gas chromatography column of FIG. 13.

### DETAILED DESCRIPTION OF THE INVENTION

Gas chromatographs rely on discrete hollow columns or channels which contain or are packed with stationary support materials for separation of gases passing therethrough. Recently, carbon nanotubes (CNTs) including single-walled carbon nanotubes (SWNTs) and multi-walled carbon nanotubes (MWNTs) have been considered for use as the stationary support materials of chromatograph columns (see for example U.S. Published Patent Application 2008/0175785; Fonveme et al., 2008; Karwa et al., 2006; Yuan et al., 2006; Reid et al., 2009; Stadermann, et al., 2006; and Saridara et al., 2005, as noted above). However, the CNT-bearing chromatographic columns and channels described in the above references have not been used in the context of microelectromechanical systems (MEMS) for analysis of natural gas either in situ in a borehole, or at the well site. The present invention, as described in further detail below, is directed to such gas chromatographic columns and apparatus, and gas chromatographs containing them, and methods of their use, in these embodiments, as well as others, and to methods of their production as discussed further herein.

Embodiments of the invention and aspects thereof are therefore directed to a gas chromatography apparatus and system that incorporates micro-scale components, partially, or completely. In particular the invention is directed to a column having a CNT stationary phase, and is suitable for use in a variety of environments. Traditionally, gas chromatographic analysis is performed above the borehole, on the surface of the earth, usually in a laboratory or similar environment. A sample may be collected at a remote location or sample site, for example, an underground or underwater location, and then returned to a testing facility, such as a laboratory, for chromatographic analysis. As discussed above, although there have been some developments of portable gas chromatography systems, few have been suitable for “on site” applications at or near the wellhead. Therefore, to address these and other limitations in the prior art, aspects and embodiments of the invention are directed to a gas chromatography system having an architecture that allows for operation at or near the wellhead, or even downhole in the wellbore. In a preferred embodiment of the invention, the gas chromatograph of the present invention is a MEMS device completely micro-fabricated on a substrate, such as a wafer, and is associated with a sampling device at the surface of the borehole (although components thereof may be downhole).

According to one embodiment, a gas chromatography system of the present invention that includes MEMS components may be arranged in a tubular housing, the housing having as small an outer diameter as feasible, and as contemplated herein are well-suited to downhole applications. For example, boreholes are typically small diameter holes having a diameter of approximately 5 inches or less. In addition, high temperature and high pressure are generally experienced in downhole environments. Therefore, the components of and/or housing of the apparatus of the present invention are able to accommodate these conditions. For example, in one embodiment, a gas chromatography apparatus may include various thermal management components. In addition, a surface-located, or downhole-located, gas chromatography apparatus according to embodiments of the invention may be a self-contained unit including an on-board supply of carrier gas and on-board waste management containers and systems. These and other features and aspects of the gas chromatography apparatus according to embodiments of the invention are discussed in more detail below with reference to the accompanying description of the drawings.

Further, it is to be appreciated that this invention is not limited in its application to the details of construction and the arrangement of components set forth in the following description or illustrated in the drawings. The invention is capable of other embodiments and of being practiced or of being carried out in various ways. For example, it is to be appreciated that the gas chromatography apparatus described herein is not limited to use with or in boreholes (above-ground, or below-ground) or other gasfield or oilfield situations and may be used in a variety of environments and application such as, for example, other underground applications, underwater and/or space applications or any application where it is desirable to have a micro-scale gas chromatograph, such as in an underground mine, a gas or oil pipeline, or in a residential or commercial building or structure (e.g., a basement or crawlway). For example, the gas chromatograph of the present invention may be designed and constructed in such a manner as to be sized so that an individual person or animal can carry the unit for use in circumstances where the ability to use a gas heretofore chromatograph is desirable but is not feasible or possible due to the size and bulkiness of gas chromatographic units. Examples of specific implementations are provided herein for illustrative purposes only and are not intended to be limiting. In particular, acts, elements and features discussed in connection with one embodiment are not intended to be excluded from a similar role in other embodiments. Also, the phraseology and terminology used herein is for the purpose of description and should not be regarded as limiting. The use of “including,” “comprising,” “having,” “containing,” “involving,” and variations thereof herein, is meant to be broad and to encompass the items listed thereafter and equivalents thereof as well as additional subject matter not recited.

As indicated above, the apparatus of the present invention may be used in association with a wellbore. Wellbores are drilled to locate and produce hydrocarbons. A downhole drilling tool with a bit at an end thereof is advanced into the ground to form a wellbore. As the drilling tool is advanced, a drilling mud is pumped from a surface mud pit, through the drilling tool and out the drill bit to cool the drilling tool and carry away cuttings. The fluid exits the drill bit and flows back up to the surface for recirculation through the tool. The drilling mud is also used to form a mudcake to line the wellbore.

Fluids, such as oil, gas and water, are commonly recovered from subterranean formations below the earth's surface. Drilling rigs at the surface are often used to bore long, slender wellbores into the earth's crust to the location of the subsurface fluid deposits to establish fluid communication with the surface through the drilled wellbore. The location of subsurface fluid deposits may not be located directly (vertically downward) below the drilling rig surface location. A wellbore which defines a path which deviates from vertical to some laterally displaced location is called a directional wellbore. Downhole drilling equipment may be used to directionally steer the wellbore to known or suspected fluid deposits using directional drilling techniques to laterally displace the borehole and create a directional wellbore. The path of a wellbore, or its “trajectory,” is made up of a series of positions at various points along the wellbore obtained by using known calculation methods.

The drilled trajectory of a wellbore is estimated by the use of a wellbore or directional survey. A wellbore survey is made up of a collection or “set” of survey-stations. A survey station is generated by taking measurements used for estimation of the position and/or wellbore orientation at a single position in the wellbore. The act of performing these measurements and generating the survey stations is termed “surveying the wellbore.”

Surveying of a wellbore is often performed by inserting one or more survey instruments into a bottom hole assembly (BHA), and moving the BHA into or out of the wellbore. At selected intervals, usually about every 30 to 90 feet (10 to 30 meters), the BHA, having the instruments therein, is stopped so that measurement can be made for the generation of a survey station. Therefore, it is also contemplated herein that the present invention may comprise a component or instrument of such a BHA.

Directional surveys may also be performed using wireline tools. Wireline tools are provided with one or more survey probes suspended by a cable and raised and lowered into and out of a wellbore. In such a system, the survey stations are generated in any of the previously mentioned surveying modes to create the survey. Often wireline tools are used to survey wellbores after a drilling tool has drilled a wellbore and a survey has been previously performed. The micro-scale gas chromatograph of the present invention may thus comprise, in an alternate embodiment, a component of such a wireline tool, as well as of a BHA, for example, and indeed may also comprise a component of a downhole drilling tool used to drill a wellbore.

As used herein, the embodiments disclosed herein are generally described for separating components from a gas sample such as a sample of natural gas. Those having ordinary skill in the art will appreciate that any composite gas known in the art, and not only natural gas, may be used to be separated into smaller components of the gas in accordance with embodiments disclosed herein.

Embodiments disclosed herein, as noted previously, relate to a gas analyzer that is, in a preferred embodiment, at least partially (or completely) disposed or formed upon a substrate such as a silicon-based substrate, for example a microchip. The substrate upon which the gas analyzer and/or CNT column component is disposed, formed, or otherwise constructed (which may also be referred to herein as a “wafer”) can be constructed, for example, of silicon, glass, sapphire, or various types of other materials, such as gallium arsenide, or a Group III-IV material. The substrate can either be doped or undoped and can be provided with a variety of orientations such as <1-0-0>, <1-1-0>, or <1-1-1>. The gas analyzer may be connected to a sampler located at a wellhead to provide a natural gas sample from a wellbore and to a carrier gas source for providing a carrier gas, and includes an injector block and one or more micro-fabricated column blocks. The injector block of the gas analyzer is used to create a gas sample from the natural gas (or other gas or gaseous fluid), and then uses the carrier gas to carry the gas sample through the remainder of the gas analyzer (i.e., the column block). As the sample gas is received within the one or more column blocks, the gas sample is separated into at least two components. These components may then be eluted from the gas analyzer, or the components may be passed onto other column blocks for further separation or detection. Preferably the injector, CNT column, and detector are all micro-fabricated.

As noted, because this gas analyzer is disposed at least partially upon a substrate such as a silicon-based microchip, embodiments disclosed herein may comprise a valve, such as a micro-valve, that may be incorporated into the gas analyzer. The valve may be machined into the substrate, and may further comprise a flexible membrane, and a rigid membrane substrate. In one embodiment, a loop groove and a conduit are machined or formed onto the substrate, and the flexible membrane or substrate is disposed over the substrate and the rigid membrane is disposed on top of the flexible membrane. The conduit is formed in a way such that pressure may be used to push the flexible membrane to open and close the conduit. As the conduit then opens and closes, gas flowing through the conduit may pass through or be impeded, thereby opening and closing the valve to enter the micro-fabricated column comprising the CNT stationary phase contemplated herein.

As mentioned above, the micro-scale gas analyzer contemplated herein may comprise multiple column blocks for separating the natural gas sample into different components. Natural gas, as contemplated herein, is any gas produced from oil or gas reservoirs from exploration to production, generally has many components, the main components being nitrogen, carbon dioxide, hydrogen sulfide, methane, and various other alkanes particularly C₂-C₆ alkanes. To separate these various components of the natural gas from one another, it may be desired to have several micro-scale column blocks with various separation columns for use in parallel or within a series. Further, though oxygen is not naturally present within natural gas, oxygen may still contaminate the natural gas source and/or the gas sample. Therefore, oxygen may be another component of interest to be identified in the gas sample. Because of the various components present within the gas sample, a preferred carrier gas used within the embodiments disclosed herein is helium. Helium already has a high mobility, in addition to generally not being a component of the natural gas within the gas sample, so this may help avoid complications when separating the components of the gas sample. However, those having ordinary skill in the art will appreciate that the present invention is not limited to only the use of helium as a carrier gas, and other gases such as nitrogen, argon, hydrogen, air, and other carrier gases known in the art may be used.

Further still, a thermal conductivity detector (TCD) may be used for the detector to detect and differentiate between the separated components of the gas sample. Recent developments in technology have significantly decreased the sizes of TCDs, such as by micro-machining the TCDs, while still allowing for very accurate readings. Natural gas analyzers with these TCDs thus may be very small, but still capable of detecting traces of gases, such as down to a few parts-per-million (ppm) or parts-per-billion (ppb). However, those having ordinary skill in the art will appreciate that the present invention is not so limited, and any detectors known in the art, such as flame ionization detectors (FIDs), electron capture detectors (ECDs), flame photomeric detectors (FPDs), photo-ionization detectors (PIDs), nitrogen phosphorus detectors (NPDs), and HALL electrolytic conductivity detectors, may be used without departing from the scope of the present invention. Each of these detectors may then include an electronic controller and signal amplifier when used within the natural gas analyzer.

As noted above, in accordance with embodiments disclosed herein, to improve the versatility of the natural gas analyzer, and/or the CNT-bearing separation column, the natural gas analyzer may be machined (e.g., micro-machined) or formed onto a substrate, such as a silicon microchip (or other microchip or wafer described elsewhere herein), such that the natural gas analyzer includes a gas chromatograph as a (micro-fabricated) micro-electro-mechanical system (MEMS). As such, a sampling loop, the one or more separation columns, and each of the valves, where present, of the natural gas analyzer may be formed onto the substrate. Further, due to the properties of natural gas and the components included therein, the substrate of the natural gas analyzer contemplated herein preferably is formed from a material that is resistant to sour gases. For example, the substrate of the natural gas analyzer may be formed from silicon, which is chemically inert to the sour gas components of natural gas, such as carbon dioxide and hydrogen sulfide. Similar to the substrate, preferably the flexible membranes and the rigid substrate or membrane of the micro-valve, where present, are formed from materials inert to the sour gas components of natural gas. For example, the flexible membranes may be formed from polymer film, such as PEEK polymer film available from VICTREX, or any other flexible membrane known in the art, and the rigid substrate or membrane may be formed from glass, or any other rigid substrate known in the art.

The terms “column,” “channel,” “chromatography column,” “micro-channel,” and variations thereof, are used interchangeably herein to refer to the separation column or components thereof comprising the CNTs disposed therein or thereon.

The terms “nanotube,” “carbon nanotube,” “CNT,” “nanofiber” and “fibril” are used interchangeably to refer to single walled or multiwalled carbon nanotubes. Each refers to an elongated structure preferably having a cross-section or a diameter (e.g., rounded) typically less than 1 micron, or 100 nm (for MWNTs) or less than 5 nm (for SWNTs). The term “nanotube” also is intended to include the terms “bucky-tubes,” and “fishbone fibrils”.

MWNTs as used herein refer collectively to CNTs which are substantially cylindrical, graphitic nanotubes of substantially constant diameter and comprise two (for DWNTs) or more (for MWNTs) cylindrical graphitic sheets or layers whose c-axes are substantially perpendicular to the cylindrical axis, such as those described, e.g., in U.S. Pat. No. 5,171,560 issued to Tennent, et al.

SWNTs as used herein refer to carbon nanotubes which are substantially cylindrical, graphitic nanotubes of substantially constant diameter and comprise a single cylindrical graphitic sheet or layer whose c-axis is substantially perpendicular to their cylindrical axis, such as those described, e.g., in U.S. Pat. No. 6,221,330 to Moy, et al.

The term “functional group” refers to groups of atoms that give the compound or substance to which they are linked characteristic chemical and physical properties. A “functionalized” surface refers to a CNT surface on which chemical groups are adsorbed or chemically attached. The term “aggregate” refers to a dense, microscopic particulate structure comprising entangled CNTs. The term “micropore” refers to a pore which has a diameter of less than 2 nanometers. The term “mesopore” refers to pores having a cross-section greater than 2 nanometers and less than 50 nanometers. The term “surface area” refers to the total surface area of a substance measurable by the BET technique. The term “accessible surface area” refers to that surface area not attributed to micropores (i.e., pores having diameters or cross-sections less than 2 nm).

SWNTs typically have smaller diameters (which may be <1 nm) than MWNTs. Thus, stationary phases created from SWNTs typically will have significantly greater specific surface area (m²/g) and lower density than stationary phases comprising MWNTs. Surface area can be a critical performance parameter for many applications that use CNTs structures, such as those listed in this application. Thus, at least for some applications, it is preferred that the stationary phase comprises SWNTs or MWNTs having smaller diameters, in an effort to maximize surface area.

Additionally, SWNT stationary phases can have smaller effective pore size than MWNT phases. Having smaller effective pore size may be beneficial in many applications, and undesirable in other circumstances. For example, smaller pores result in catalyst supports having higher specific surface areas. Conversely, smaller pores are subject to diffusion limitations and plugging. Thus, the advantages of smaller pore size need to be balanced against other considerations. Parameters, such as total porosity, and pore size distribution, become important qualifiers of effective pore size. Thus while MWNT assemblages, networks, rigid porous structures and extrudates may have specific surface areas between 30 and 600 m²/g, the corresponding SWNT assemblages, networks, structures and extrudates may have specific surface areas between 1000 and 2500 m²/g.

The stationary phase separation columns of the present invention may contain either or both SWNTs and MWNTs. Particular types of catalytic metals or combinations thereof, such as cobalt-molybdenum may preferentially form SWNTs when the metal is deposited on the substrate in a particular fashion and ratio. CNT structures comprising both MWNTs and SWNTs can retain the high specific surface area and small effective pore size associated with SWNTs while retaining substantial macroporosity associated with MWNTs. MWNTs also are easier to functionalize. Thus, in an exemplary embodiment, a CNT mixed structure of the present invention contains MWNTs to provide the integrity and physical conformation of the structure, and SWNTs to provide the effective surface area. These structures thus may exhibit a bimodal pore size distribution. The mixed structures have densities between 0.001 and 0.50 g/mL, preferably between 0.05-0.5 g/mL. The mixed structures, for example, have surface areas between 300-1800 m²/g, preferably between 500-1000 m²/g.

The ratio of SWNTs to MWNTs in the mixed CNT structure may range from, but is not limited to, 1/1000 to 1000/1 by weight, or 1/100 to 100/1, or 1/10 to 10/1. Preferably, the ratio of SWNTs to MWNTs in the CNT stationary phase may range from 1/1000 to 100/1 by weight, or 1/10 to 100/1, or from 1/1000 to 10/1 by weight, or 1/100 to 10/1. Alternatively, the ratio of SWNTs to MWNTs in the CNT phase may range from 1/1000 to 1/1 by weight, or 1/100 to 1/1, or 1/10 to 1/1, or 1/1 to 1000/1 by weight, or 1/1 to 100/1, or 1/1 to 10/1.

The CNT structures of the micro-fabricated columns of the present invention include, but are not limited to, macroscopic two and three dimensional structures of carbon nanotubes such as assemblages, mats, plugs, networks, “forests,” rigid porous structures, and extrudates.

As noted above, in a preferred embodiment the micro-scale gas chromatograph is operated at the wellbore surface. However, in another embodiment, the micro-scale gas chromatograph and separation column of the present invention is a component of a downhole tool which may be lowered through a tubing positioned within a gas well or oil well wellbore which is lined with a casing. Preferably a packer is positioned between the tubing and the casing to isolate the tubing-casing annulus. The downhole tool is run on a carrier which may be a wireline, slickline, tubing or other carrier, and which may include one or more electrical conductors for carrying power or signals to the components of the downhole tool.

The wellhead-disposed, surface-disposed, or downhole device may comprise other components known in the art. For example, the gas analyzer of the invention may comprise switches which include microelectromechanical elements, which may be based on microelectromechanical system (MEMS) technology. MEMS elements include mechanical elements which are moveable by an input energy (electrical energy or other type of energy). MEMS switches, as noted earlier, may be formed with micro-fabrication techniques, which may include micromachining on a semiconductor substrate (e.g., silicon substrate). In the micromachining process, various etching and patterning steps may be used to form the desired micromechanical parts. Some advantages of MEMS elements are that they occupy a small space, require relatively low power, are relatively rugged, and may be relatively inexpensive.

Switches according to other embodiments may be made with microelectronic techniques similar to those used to fabricate integrated circuit devices. As used here, switches formed with MEMS or other microelectronics technology may be generally referred to as “micro-switches.” Elements in such micro-switches may be referred to as “micro-elements,” which are generally elements formed of MEMS or microelectronics technology. Generally, switches or devices implemented with MEMS technology may be referred to as “microelectromechanical switches.”

In one embodiment, micro-switches may be integrated with other components. As used here, components are referred to as being “integrated” if they are formed on a common support structure placed in packaging of relatively small size, or otherwise assembled in close proximity to one another. Thus, for example, a micro-switch may be fabricated on the same support structure (substrate) as the separation column, injector, and/or detector.

Reference is now made to the drawings, illustrations, pictures and descriptions below which are exemplary, but not limiting, of the present invention.

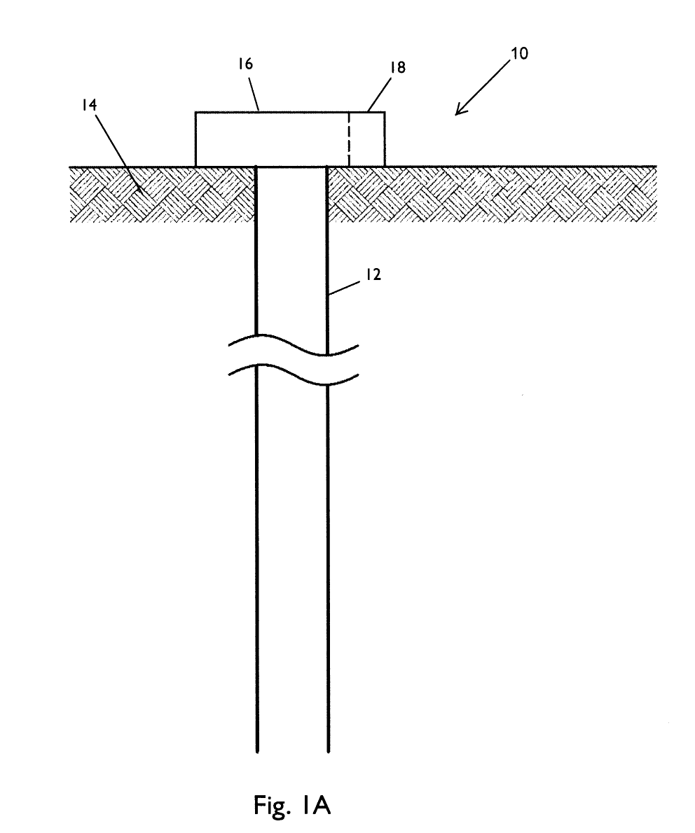

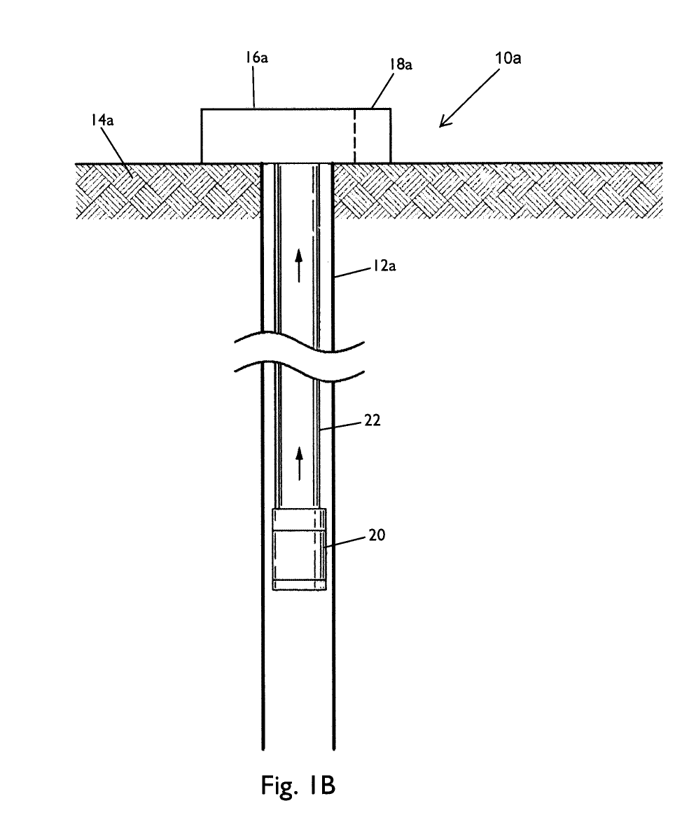

FIG. 1A is a schematic representation in cross-section of an exemplary operating environment of the present invention comprising a wellsite 10 having a borehole (or wellbore) 12 drilled into a geologic formation 14. FIG. 1A further depicts a gas sampling system 16 and a gas analyzer 18 of the present invention positioned at the wellhead.

FIG. 1B is an exemplary embodiment comprising a wellsite 10a having a borehole 12a drilled into a geologic formation 14a. A gas sampling system 16a is associated with a gas analyzer 18a which is the gas analyzer described elsewhere herein. A borehole tool 20 is suspended in the borehole 12a from a lower end of a wireline or borehole tubing 22. The wireline or borehole tubing 22 may be operationally and electrically coupled to the gas sampling system 16a and the gas analyzer 18a.

The borehole tool 20 comprises a body which encases a variety of electronic components and modules, which are schematically represented in FIG. 1B, for providing necessary and desirable functionality to the borehole tool 20.

The gas analyzer 18a of the present invention, in its various embodiments, may preferably include a control processor (not shown) which is operatively connected with the borehole tool 20 and/or gas analyzer 18a of the invention. Preferably, certain methods of the present invention are embodied in a computer program that runs in or is associated with the gas analyzer 18a. In operation, the program may be coupled to receive data, for example, via the wireline 22, and to transmit control signals to operative elements of the borehole tool 20.

The computer program may be stored on a computer usable storage medium associated with the processor (not shown), or may be stored on an external computer usable storage medium and electronically coupled to processor 40 for use as needed. The storage medium may be any one or more of presently known storage media, such as a magnetic disk fitting into a disk drive, or an optically readable CD-ROM, or a readable device of any other kind, including a remote storage device coupled over a switched telecommunication link, or future storage media suitable for the purposes and objectives described herein.

As noted, the gas chromatograph comprising the micro-scale column of the present invention is preferably adapted for surface use at a well-site (FIG. 1A) or may be contained within a downhole tool adapted to drill or survey the wellbore and which is operatively connected to a rig via a drill string, pipe line or wireline. The downhole drilling tool may comprise a wellbore survey tool, a downhole communication unit, a rotary steerable system, a measurement-while-drilling system, a logging-while-drilling tool, a testing tool, and/or a sampling tool.

The downhole tool may also be provided with a downhole communication network for establishing communication between the various downhole components and can be formed by any suitable type of communication system, such as an electronic communication system, or an optical communication system. The electronic communication system can be either wired or wireless, and can pass information by way of electromagnetic signals, acoustic signals, inductive signals, and/or radio frequency signals.

As noted elsewhere herein, the micro-scale CNT column may also be part of a downhole tool which can be any type of deployable tool capable of performing formation evaluation or surveying in a wellbore such as a wireline tool, a coiled tubing tool, a slick line tool or other type of downhole tool. The downhole tool may be a conventional wireline tool (except for the addition of the apparatus of the present invention or as described elsewhere herein) deployed from the rig into the wellbore via a wireline cable and positioned adjacent to a subterranean formation. An example of a wireline tool that may be used is described in U.S. Pat. Nos. 4,860,581 and 4,936,139.

The downhole tool may comprise modules such as testing modules, sampling modules, hydraulic modules, electronic modules, a downhole communication unit, or the like. The downhole communication unit can be a telemetry unit, such as an electromagnetic or mud pulse unit, or a wireline communication unit, an acoustic communication unit, or a drill pipe communication unit. In general, the downhole communication unit is linked to and utilized with a surface unit for retrieving and/or downloading information to the surface unit.

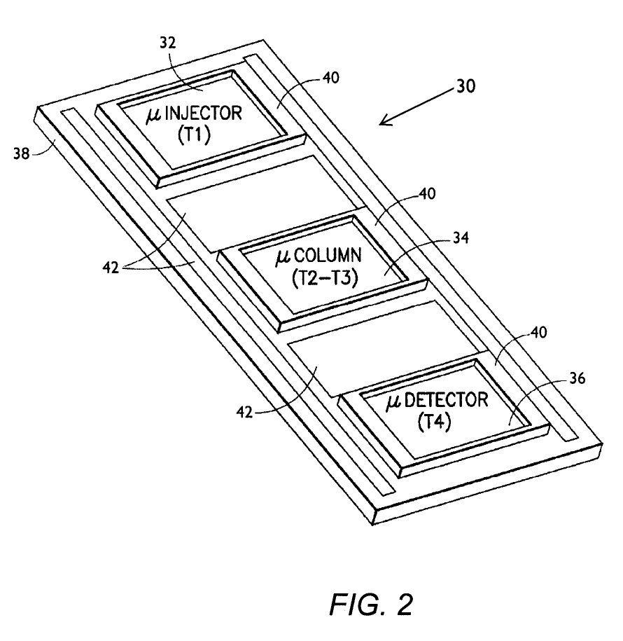

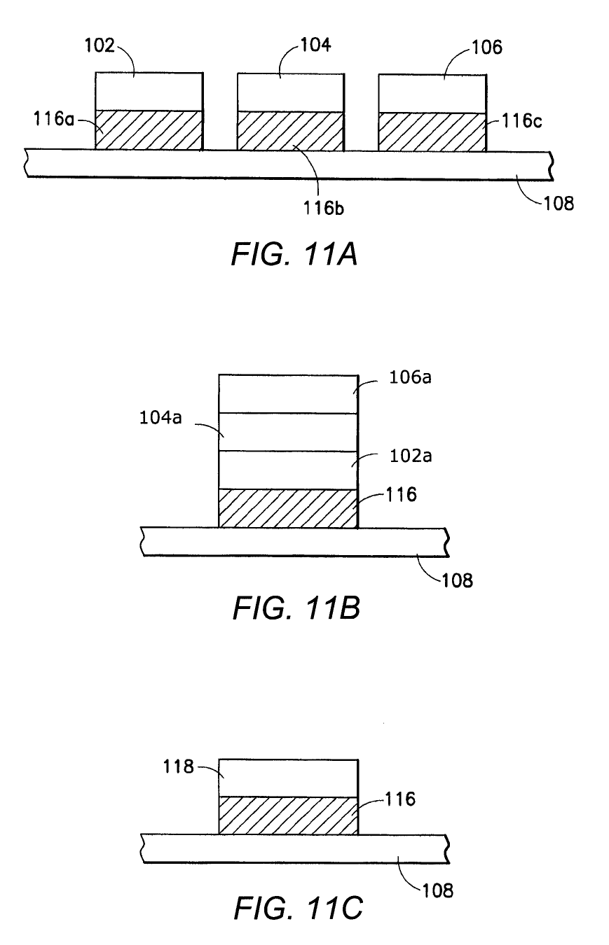

A micro-scale gas chromatography architecture contemplated for use in the present invention can provide major advantages for effective thermal management. For example, the small size of micro-scale components equates to lower thermal mass. This makes temperature control of the components easier because there is a lower mass to be heated and/or cooled. According to one embodiment, the management of temperature transitions between components of the injector, column and detector may be controlled by incorporation of thermal stops and traps, as shown in FIG. 2 which illustrates a MEMS micro-scale gas analyzer 30 of the invention which comprises micro-fabricated components including a micro-injector 32, CNT micro-column 34 and micro-detector 36 coupled to a micro-fluidic platform 38 and optionally including thermal stops 40 and thermal traps 42. A thermal stop is a heated extra mass, sized to preserve the stability of temperature at the perimeter of the heated micro-device. A thermal trap, on the other hand, is a void filled with thermal insulator that limits heat transfer and thus heat loss from the isolated component. Each component of the micro-scale gas analyzer may be provided with a heater (not shown) that may set a desired temperature, or provide a ramped temperature, for each component. Using the thermal stops and thermal traps, the uniformity of temperature within the heated components may be independently preserved. The heaters may be, for example, ceramic heaters or Peltier devices. Peltier devices may be formed as a flat plate that may fit between a GC component and the micro-fluidic platform, as illustrated below, for example, in FIGS. 11A-11C. Peltier devices have the property that when electricity is supplied, one side of the device heats up while the other side cools down. Thus, by providing a controlled supply of electricity to a Peltier device, local heating and/or cooling may be provided for each GC component. For example, the injector 32 may be operated at a first temperature, T₁, the column 34 operated over a range of temperatures, T₂-T₃, and the detector 36 operated at a third temperature, T₄. These different temperatures may be maintained at the individual devices by using the heaters together with the thermal traps 42 and stops 40 to isolate the components 32, 34, and 36 from one another. With all or at least some of the GC components being at the micro-scale, such thermal management may be intrinsically easier to achieve.

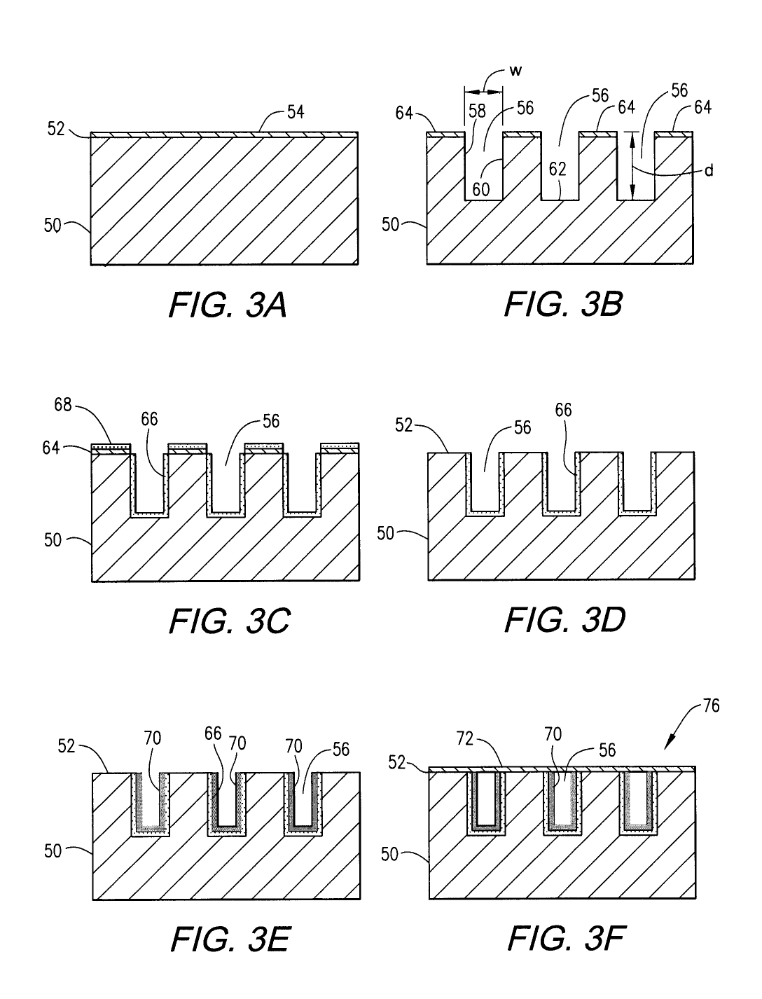

Described below is one embodiment of a micro-fabrication process for a carbon nanotube coated MEMS column of the present invention, with examples of final devices and demonstration of the retention capabilities for natural gas analysis and separation of hydrocarbons such as hexane and smaller alkanes (C₁-C₅). FIG. 3 is exemplary of the different steps of the micro-fabrication process to make the CNT column of the present invention. A substrate (also referred to herein as a “wafer”) 50 having an upper surface 52 is provided. Examples of substrate materials which may be used are described elsewhere herein. A photoresist material is spin-coated onto the upper surface 52 to form a photoresist layer 54 thereon. Photoresist materials and their application are known in the art thus further discussion thereof is not considered necessary herein. Photolithography and Deep Reactive-Ion Etching (DRIE) or an equivalent technique is then used for the anisotropic etching of micro-channels 56 (FIG. 3B) in a predetermined pattern. Each micro-channel 56 has a first side wall 58, a second side wall 60 and a bottom 62 (all of which may be referred to herein as “inner walls”). Residual portions 64 of the photoresist layer 54 are left after the etching process. Each micro-channel 56 has a depth “d” which is preferably in a range of from 10 micrometers to 500 micrometers and a width “w” which is preferably in a range of from 10 micrometers to 500 micrometers. Processes such as DRIE for micro-fabricating micro-scale channels, micro-valves, and other components in wafers such as silicon-on-insulator wafers are known to persons of ordinary skill in the art, thus extensive discussion herein of such processes and techniques is not considered to be necessary, however, description of such techniques can readily be found for example in U.S. Published Application 2008/0121017, for example in paragraphs 101-108 thereof. Thin film catalysts made of, for example, but not limited to, nickel or kanthal (an alloy of iron, chromium (20-30%), aluminum (4-7.5%) and optionally trace amounts of cobalt) are then sputtered onto the etched wafer with a total thickness that varies from 1 to 100 nm (FIG. 3C). The thin film catalyst forms a catalyst layer 66 on the side walls 58 and 60, and bottom 62 of the micro-channel 56. The catalyst layer 66 may have a thickness of from 1 nm to 100 nm, for example. Catalyst is also deposited upon the residual photoresist portions 64 and are shown as catalyst portions 68. The wafer 50 is then sonicated in acetone for 5 to 10 minutes to remove the residual photoresist portions 64 and catalyst portions 68 thereon (FIG. 3D). This is followed by a process such as chemical vapor deposition (CVD) for the in situ growth of a CNT mat 70 on the catalyst layer 66 (FIG. 3E). Any suitable method of CNT growth (including CVD) may be used. Following the CNT growth, the last step (FIG. 3F) of the process is the anodic bonding of a cover 72 to the processed wafer 50. The cover 72 may be for example a Pyrex wafer and once bonded forms a sealed MEMS column 76. The thickness of the CNT mat 70 is preferably in a range of from 50 nm to 50 micrometers. Preferably the CNTs are grown over a period of 1 minute to 60 minutes and are preferably grown at a rate which results in an increase in the thickness of the CNT mat 70 at a rate of 0.1 micrometer to 1 micrometer per minute

Where used herein to refer to the thickness of the CNT mat 70 within the micro-channel 56 of the micro-fabricated column, the terms “uniform,” “uniformly,” or “uniformity” are intended to mean that the thickness of the CNT mat 70 in the micro-channel 56 is substantially constant from the entrance of the column to the exit of the column on a particular inner wall surface (e.g., side wall 58 or 60, or bottom 62). For example the thickness preferably is constant within a range of plus or minus 25% of an average of the thickness of the CNT mat 70. For example, if the average thickness of the CNT mat 70 on side wall 58 or 60, or bottom 62, is 100 nm, a measurement of the thickness of the CNT mat 70 at any specific position on the sidewall 58 or 60, or bottom 62, of the micro-channel 56 will be between 75-125 nm.

The width “w” and depth “d” of the micro-channel 56 are each substantially uniform along the length of the micro-channel 56, that is, from the entrance to the exit thereof. The length of the micro-channel 56 from the entrance to the exit thereof is preferably in the range of 0.5 m to 5 m, and more preferably is at least 1 m in length. Similarly, the thicknesses of the catalyst layer 66 on the side walls 58 and 60 are substantially uniform along the length of the micro-channel 56. Further, the thickness of the catalyst layer 66 on the bottom 62 of the micro-channel 56 is substantially uniform along the length thereof, although the average thickness of the catalyst layer 66 on the bottom surface 62 may differ from the average thickness of the catalyst layer 66 on the side walls 58 and 60.

Various metals and alloys can be used separately or in combination as catalysts in the present invention. The metals may be selected for example from Group VIII (Co, Ni, Ru, Rh, Pd, Ir, Fe, Pt), Group VIb (Cr, W, Mo), Group Vb (V, Nb, Ta), Group VII (Mn, Tc, Re) or the lanthanides. The catalyst may comprise two or more metals from the same Group (i.e., Group VIII, VII, VIb, Vb, or the lanthanides), or from different Groups (i.e., Group VIII, VII, VIb, Vb, or the lanthanides). Preferably the catalyst comprises at least one Group VIII metal. The catalyst may comprise two or more metals, e.g., one or more from Group VIII and one or more from Group VIb, and/or one or more from Group Vb, and/or one or more from Group VII, and/or one or more lanthanides.

The metals may be applied via sputtering or other means known in the art to the surfaces of the micro-channels of the wafer or may be deposited thereon via deposition of transition metal precursors in solution, e.g. Co may be deposited as bis (cyclopentadienyl) cobalt or Mo may be deposited as bis (cyclopentadienyl) molybdenum chloride.

The ratio of the Group VIII metal to the Group VIb, or Group Vb, or Group VII, or lanthanide metal in the catalyst is, for example, but not limited to, from about 1:25 to about 25:1, and more preferably about 1:10 to about 10:1. The concentration of the Group VIb or Group Vb metal (e.g., Mo) or Group VII metal may exceed the concentration of the Group VIII metal (e.g., Co) in catalysts employed for the preferential production of SWNTs.

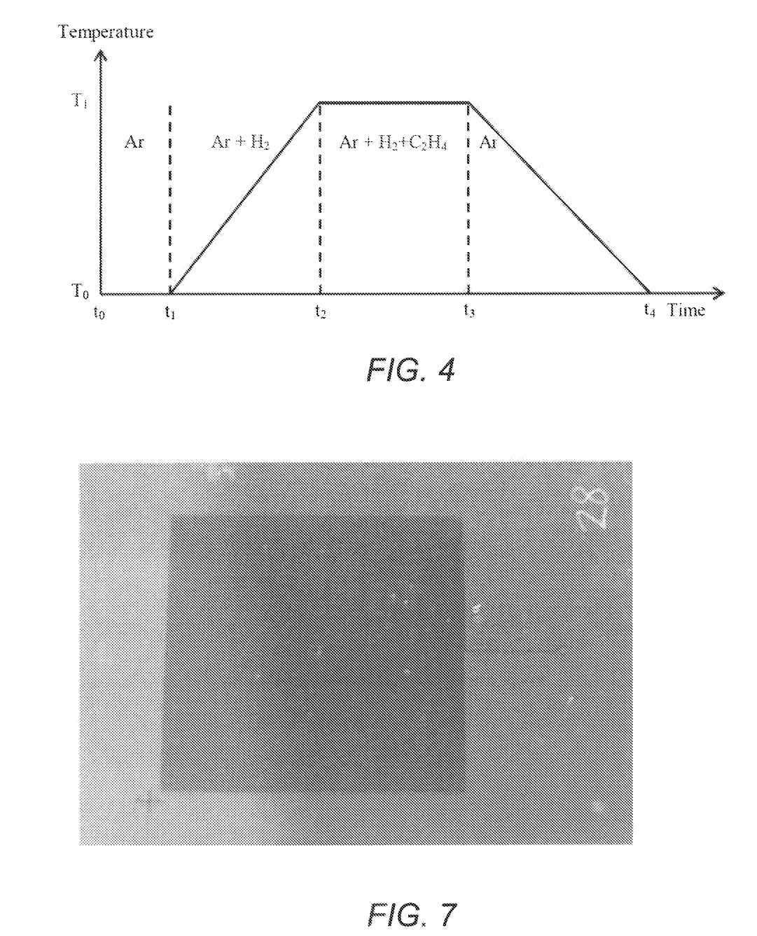

The CVD process comprises, in one embodiment, as shown in FIG. 4, five different phases where temperature and ratio of the different gases used are changed over time. The first step between t₀ and t₁ is a flush of the system with argon during 1 to 5 minutes at room temperature T₀. The second step takes from 15 to 25 minutes to increase the temperature of the CVD oven to T₁ that ranges between 500° C. and 1100° C. The third step at high temperature T₁ lasts from 1 to 10 minutes with a mixture of argon, hydrogen and ethylene. The fourth step is a flush of argon while the CVD oven is cooled down. Examples of suitable carbon-containing gases which may be used herein during the CVD process to produce the CNTs include aliphatic hydrocarbons, both saturated and unsaturated, such as methane, ethane, propane, butane, hexane, ethylene and propylene; carbon monoxide; oxygenated hydrocarbons such as acetone, acetylene and methanol; aromatic hydrocarbons such as toluene, benzene and naphthalene; and mixtures of the above, for example carbon monoxide and methane. Use of acetylene tends to promote formation of multi-walled carbon nanotubes, while CO and methane are preferred feed gases for formation of single-walled carbon nanotubes. The carbon-containing gas may optionally be mixed with a diluent gas, such as helium, argon or hydrogen. During formation of the CNT stationary phase on the catalytic layer 66 of the micro-channel 56, in one exemplary embodiment, the flow rate of the carrier gas (e.g., argon) is about 1 L/min (though this may vary, for example, from 0.1 L/min to 10 L/min). The particular flow rate used during formation of the CNT stationary phase may depend on the configuration of the micro-fabricated column. H₂ and the carbon-providing gas (e.g., ethylene, or other carbon-based gas contemplated herein) are preferably provided in (but are not limited to) the ranges of 1:1-1:10 (hydrogen:argon) and 1:1 to 1:20 (ethylene:argon).

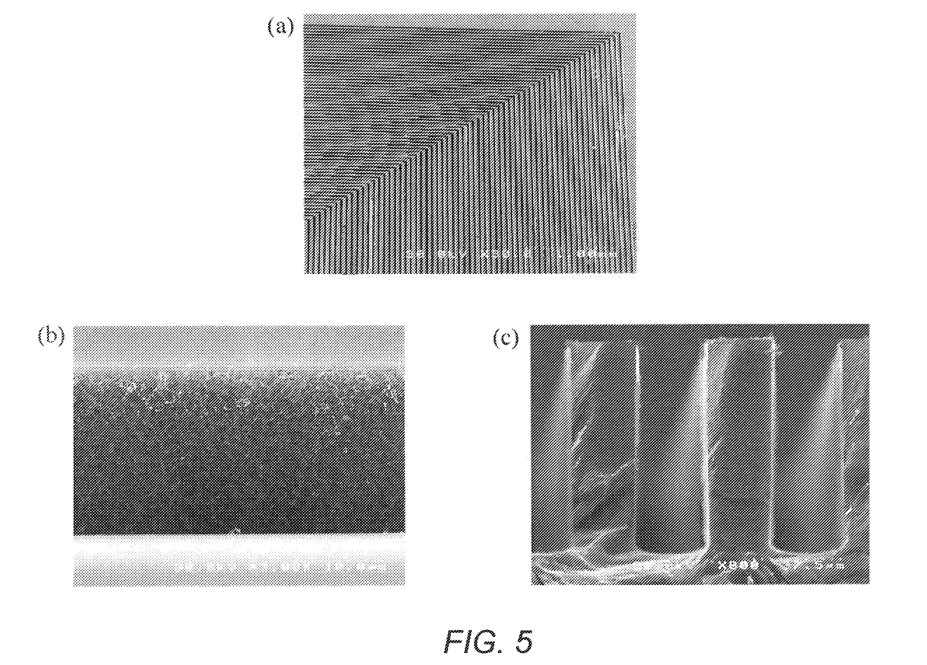

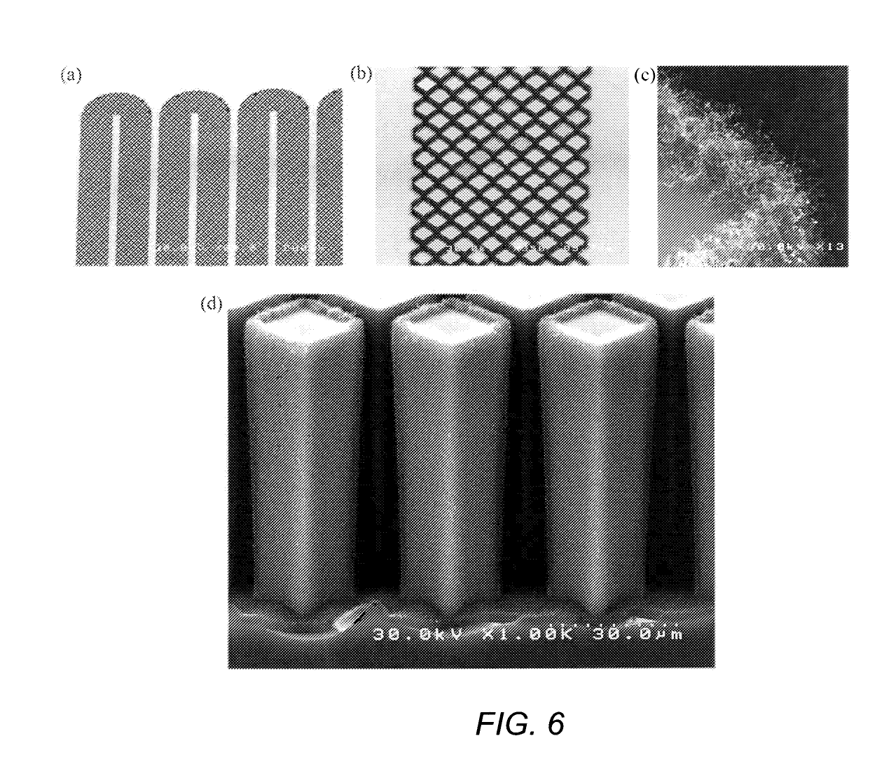

FIGS. 5(A-C) and 6(A-D) give examples of SEM pictures of micro-columns and micro-structured columns after the CVD process. Those pictures show CNT mats which cover both walls and bottom of the micro-structures of the channels, following CVD on the catalyst layer deposited by sputtering. Other reports in the literature using metal evaporation show different results where walls are not fully covered by carbon nanotube mats.

Further, parameters for the CVD process were optimized in order to avoid the deposition of amorphous carbon during the growth of CNTs. An important negative consequence of amorphous carbon deposition is that it may cover the upper surface of the silicon wafer, making it impossible to bond the Pyrex wafer cover to the silicon surface, a step that requires a very clean interface. One type of amorphous carbon is carbon black, generally in the form of spheroidal particles having a graphene structure comprising carbon layers around a disordered nucleus. Standard graphite, because of its structure, can undergo oxidation to almost complete saturation. These characteristics make graphite and carbon black poor predictors of carbon nanotube chemistry and inhibit anodization of the Pyrex cover to the silicon wafer. One solution to the problem of amorphous carbon found in Fonverne et al. (2008) is to protect this Si surface with a SiO₂ layer, which is then removed. However, the removal of the SiO₂ layer by hydrofluoric acid (HF) can also cause degradation of the CNT mat. Hence, a preferred version of the final process described herein allows for a completely dry process not relying on removal of amorphous carbon by an HF cleaning step.

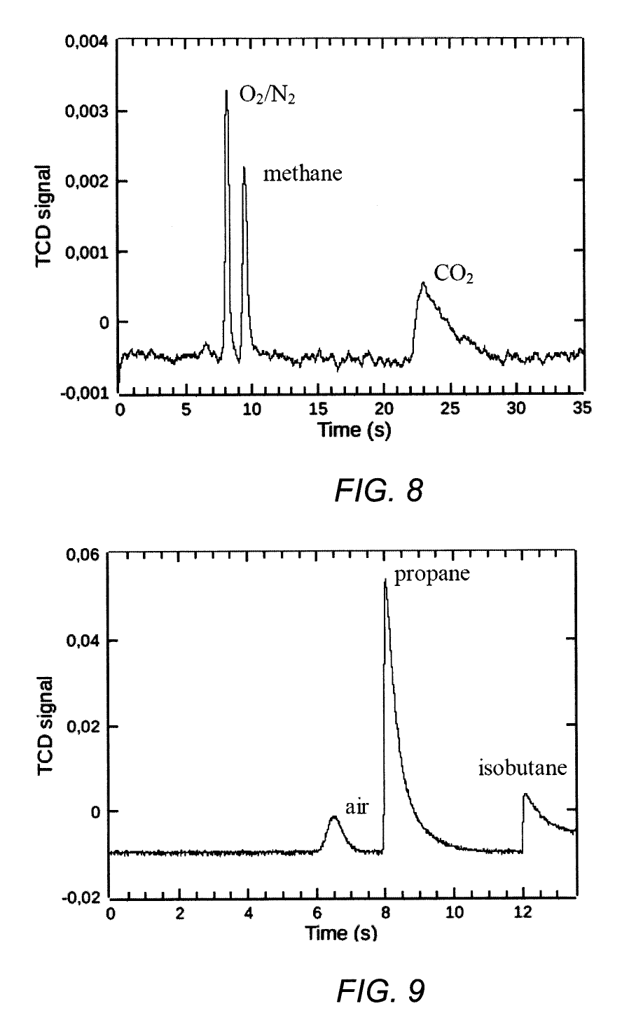

In an exemplary embodiment, nickel or kanthal are used as a catalyst to improve the adhesion of the CNT mat in the microfluidic channel. Of the number of characteristics to consider for selecting the metal catalyst, one such criteria may be the adhesion required between the nanotubes stationary phase and the channel wall. FIG. 7 is a picture of a CNT based MEMS column fabricated with the process described herein. The width and height of the fabricated columns range from few tens of microns to few hundreds of microns, and length from few tens of centimeters to few meters. As noted above, such a column has the ability to separate hydrocarbon gases below hexane (C₁-C₅), which are especially of interest for the analysis of natural gases. FIG. 8 shows an example of isothermal separation of a N₂/O₂-methane-CO₂ mixture using the CNT-based MEMS column of the present invention. FIG. 9 shows an example of isothermal separations of alkanes between ethane and pentane also using the CNT-based MEMS column of the present invention, however, having a different channel geometry than the CNT-based MEMS column used in FIG. 8. It should be understood that the separation of a N₂/O₂-methane-CO₂ mixture and the separation of alkanes between ethane and pentane may be performed under thermal ramping conditions as provided herein.

As noted elsewhere herein, an important advantage of the present invention is the significant improvement obtained in the separation of components of natural gas versus that obtained using stationary phases and column configurations conventionally known and available to those of ordinary skill in the art. In particular, the present invention optimizes the separation of methane, carbon dioxide, ethane, propanes, butanes, and pentanes. The retention times of these compounds are substantially lower than that of C₆ compounds (hexanes) and higher. Compounds with low retention times elute more quickly from the stationary phase thus reducing the efficiency of separation between the “peaks” of the constituents. Thus, methane has a lower retention time than CO₂, which has a lower retention time than ethane, which has a lower retention time than propanes, which has a lower retention time than butanes, which has a lower retention time than pentanes. As shown herein in FIGS. 8 and 9, the CNT column of the present invention cleanly separated methane from CO₂, and propane from isobutane, respectively, thus demonstrating that the CNT column of the present invention is able to cleanly separate methane, CO₂, ethane, propane, butane and pentane components from each other and from higher alkanes present in natural gas.

Further, in a preferred embodiment of the present invention the C₁-C₅ alkanes and CO₂ components of natural gas are separated by Resolution factors (“R”) of >1.5, or >2.0, or more preferably >2.5, or still more preferably >3.0 or >3.5, and yet more preferably >4.0, where R is the ratio of (1) the distance between the maxima of two peaks, and (2) the average of the base widths of the two peaks. Generally where R<=1.5, there is some overlap between the two peaks.

As explained above, the micro-fabricated CNT stationary phase column of the present invention can be used as a component of a gas chromatograph which is used as a component of a borehole tool (or borehole tool string) connected to a wireline for use in downhole analysis of formation fluids such as natural gas and other fluids such as petroleum. Provided below is further description of various embodiments of the gas chromatograph of the present invention.

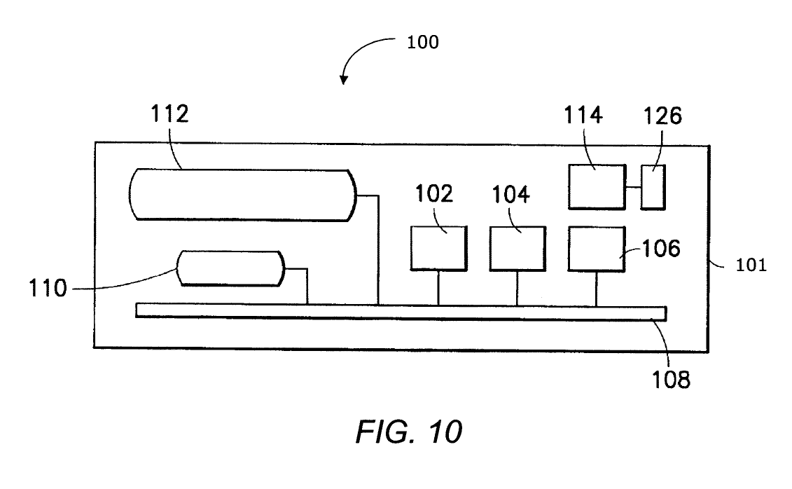

Referring now to FIG. 10, there is illustrated in a block diagram and designated therein by the general reference numeral 100 one embodiment of a gas chromatography (GC) system for use either in a surface application (such as at a well-site) or in a borehole tool 16 according to the invention. The GC system 100 may comprise a plurality of components contained within a housing 101. These components may include, for example, an injector 102, one or more gas chromatography columns 104 such as the CNT columns of the present invention and one or more detectors 106. These components are collectively referred to as GC components and are described further below. These components may be coupled to one another either directly or via a micro-fluidic platform 108 which is also discussed further below. In addition, the GC system 100 may include a power supply 126 and control components 114. In one example, the power supply 126 may include a wireline (such as wireline 18 described above) that may connect the gas chromatography system 100 to an external source of power (e.g., a generator or public electricity supply). In another example, particularly where several of the GC components may be micro-scale components, the power requirements may be sufficiently too small to allow battery operation and the power supply 126 may thus include one or more batteries. These batteries may be, for example, Lithium Thionel Chloride batteries rated for high temperature environments. As discussed above, the GC system 100 may also include a carrier gas supply 110 as well as a waste storage component 112. Having an on-board carrier gas supply 110 may allow the GC system 100 to be operated downhole (or in another remote environment) without requiring connection to an external supply of gas. In a downhole or other pressurized environment (e.g., deep underwater locations or outer space), it may be difficult, if not impossible, to vent waste gas outside of the gas chromatography system 100 due to high ambient pressure or other conditions. Therefore, the on-board waste storage component 112 may be particularly desirable. By making at least some of the system components micro-scale components, a chromatography device small enough to comply with the space constraints of downhole environments may be realized.

It is to be appreciated that although embodiments of chromatography systems of the present invention may be referred to herein as micro-scale systems, not all of the components are required to be micro-scale and at least some components may be meso-scale or larger. This is particularly the case where the device is intended for use in environments where the space constraints are not as tight as for downhole applications. As used herein, the term “micro-scale” is intended to mean those structures or components having at least one relevant dimension that is in a range of about 100 nm to approximately 1 mm. In order to achieve these scales, manufacturing technologies such as silicon micro-machining, chemical etching, DRIE and other methods known to those skilled in the art may be used. Thus, for example, a “micro-scale” gas chromatography column 104 is preferably constructed using a silicon wafer into which are etched or machined very small channels of the micrometer-scale width. Although the overall length of such a column 104 may be a few centimeters, (in width and/or length), a relevant feature, namely, the channels, are not only micro-scale, but also may be manufactured using micro-machining (or chemical etching) techniques. Therefore, such a column may be referred to as a micro-scale column. Such columns have very low mass when packaged and therefore allow for easier thermal management compared to traditionally packaged columns. By contrast, “meso-scale” components of a gas chromatograph, e.g., an injector and/or detector, may have relevant dimensions that may be between several micrometers and a few millimeters and may be made using traditional manufacturing methods such as milling, grinding, glass and metal tube drawing etc. Such components tend to be bulkier than components that may be considered “micro-scale” components.

As discussed above, a gas chromatography system 100 according to embodiments of the invention may comprise an injector 102, at least one column 104 and at least one detector 106 interconnected via a micro-fluidic platform 108. The micro-fluidic platform 108 may include flow channels that provide fluid connections between the various GC components, as discussed further below. It is to be appreciated that various embodiments of the GC system 100 may include one or more columns 104 that may be disposed in a parallel or series configuration. In a parallel configuration, a sample may be directed into multiple columns 104 at the same time using, for example, a valve mechanism that couples the columns 104 to the micro-fluidic platform 108. The output of each column 104 may be provided to one or more detectors 106. For example, the same detector 106 may be used to analyze the output of multiple columns 104 or, alternatively, some or all of the columns 104 may be provided with a dedicated detector 106. In another example, multiple detectors 106 may be used to analyze the output of one column 104. Multiple detectors 106 and/or columns 104 may be coupled together in series or parallel. In a series configuration of columns 104, the output of a first column 104 may be directed to the input of a second column 104, rather than to waste. In one example, a detector 106 may also be positioned between the two columns 104 as well as at the output of the second column 104. In another example, a detector 106 may be positioned only at the output of the last column 104 of the series. It is to be appreciated that many configurations, series and parallel, are possible for multiple columns 104 and detectors 106 and that the invention is not limited to any particular configuration or to the examples discussed herein.

In one embodiment of a micro-scale gas chromatograph 100, some or all of the GC components may be MEMS devices. Such devices are small and thus appropriate for a system designed to fit within the small housing 101 of chromatograph 100 suitable for well-site surface use, or even downhole deployment. In addition, such devices may be easily coupled to the micro-fluidic platform 108. In one example, some or all of the three components 102, 104 and 106 may be MEMS devices that are approximately 2 cm by 2 cm by 1-2 mm thick. Arranged linearly, as shown, for example, in FIG. 10, these devices could easily be housed within a cylinder having an inner diameter of about 2 inches or less and a length of about 4 inches. However, it is to be appreciated that the injector 102, column 104 and detector 106 need not be discrete devices and also need not be linearly arranged within the housing 101. For example, the components 102, 104, and 106 could all be on a single microchip. Many other configurations are also possible and are considered included in this disclosure. In addition, many variations on the size and thickness of the devices are also possible and the invention is not limited to the specific example given herein.

For example, referring to FIGS. 11A-11C, there are illustrated three examples of arrangements of the injector 102, column 104 and detector 106. In FIG. 11A, the GC components are illustrated in a linear arrangement, similar to that shown in FIG. 10. Such a linear configuration may be advantageous when it is desirable to keep the inner diameter of the housing 101 as small as possible and where the length of the housing 101 is less critical. This configuration may also have the advantage of allowing each discrete device 102, 104 and 106 to have individual thermal management device including, for example, individual heating devices 116a, 116b, and 116c, respectively, as shown. Therefore, this linear configuration may be preferred in application where the injector 102, column(s) 104, and detector(s) 106 are to be operated at different temperatures. In the example illustrated in FIG. 11A, the heating elements 116a-116c are shown positioned between the respective components 102, 104 and 106 and the micro-fluidic platform 108; however, it is to be appreciated that the invention is not limited to the illustrated arrangement. For example, referring to FIG. 11B, an injector 102a, a column 104a and a detector 106a are illustrated in a stacked arrangement, one on top of the other with a heating device 116 disposed thereunder. Such a stacked arrangement may be preferable if there is a need or desire to shorten the length of the housing 101. For example, the stacked components, along with other components making up the gas chromatograph system, may fit within a housing having an inner diameter of less than about 2 inches and a length of about 1.5 inches. In another embodiment, illustrated in FIG. 11C, integrated MEMS device 118 may contain an injector, column and detector disposed upon a heating device 116. In one example, such an integrated MEMS device may be less than about 2 cm by about 5 cm by about 1 to 2 mm in height. The stacked and integrated embodiments shown in FIGS. 11B and 11C may be particularly suitable for isothermal analysis where all active components are held at the same temperature. In these examples, one heater 116 may suffice for all of the injector, column and detector components.

According to one embodiment, and referring again to FIG. 10, a micro-scale GC chromatograph 100 according to aspects of the invention may comprise one or more components at the micro-fluidic scale, wherein the flow channels are very small. For example, in one embodiment, the flow channels may be on the order of about 1 μm-1000 μm and more preferably 5 μm-100 μm. Volumetric flow rates of carrier gas through the flow channels scale approximately as the square of the effective diameter of the channel. Therefore, a micro-scale gas chromatography system 100 may inherently require a significantly smaller supply of carrier gas when compared to a meso-scale or larger scale system. In one example, a micro-scale gas chromatography apparatus may consume carrier gas at a rate 5 or even 10 times slower than a traditional, larger gas chromatography system that includes much larger flow channels. This may be advantageous in that both the carrier gas supply 110 and waste storage component 112 (see FIG. 10) may be comparatively smaller as they may contain a smaller volume of gas. For example, assuming that the carrier gas consumption for a micro-scale gas chromatograph 100 is on the order of about 100 microliters per minute (μL/min), for a 1000-minute service downhole, 100 milliliters (mL) of carrier gas may be required. Assuming that the analysis is performed at near-atmospheric pressure (approximately 15 psi), a waste storage container 112 of about 100 mL would be needed. In one embodiment, the carrier gas supply may be stored in a high-pressure (e.g., about 1000 psi) container 110 and thus, the size of the container 110 may be extremely small.

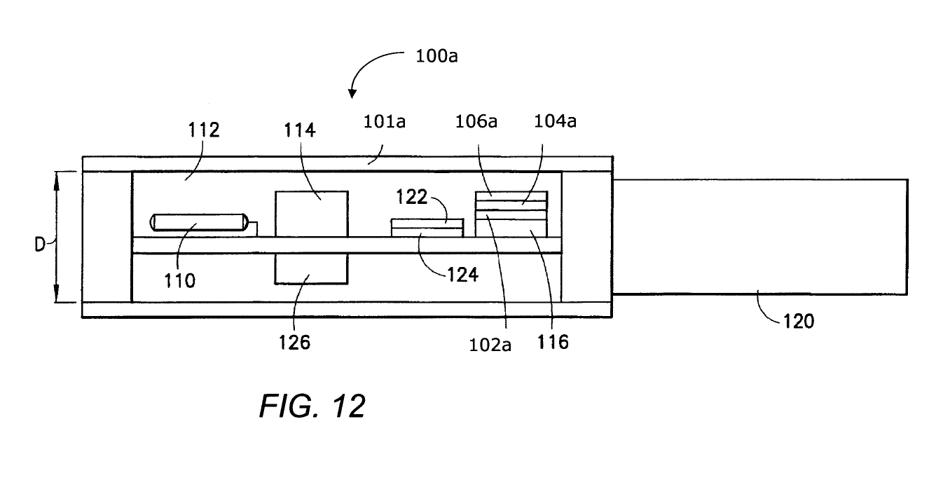

Referring now to FIG. 12, there is illustrated a block diagram of another embodiment of a gas chromatography apparatus 100a according to the invention. In this embodiment, an injector 102a, column 104a and detector 106a are shown in a stacked arrangement (e.g., as in FIG. 11B), one on top of the other. However, it is to be appreciated that any of the above-mentioned configurations of FIGS. 11A-11C may be used. Also shown are some thermal management components including the heater(s) 116 discussed above and a cooler 120. These components are discussed in more detail below. In the illustrated embodiment, a housing 101a contains the GC components, the micro-fluidic platform 108, carrier gas container 110 and other components, may also serve as the waste storage container 112. This may eliminate the need for a separate waste storage container which may reduce the overall size of the system. In one example of this embodiment, the housing 101a may be a cylinder that has an inner diameter D of about 2 inches and a length of about 8 inches.

According to some embodiments of the invention, a gas chromatography system 100a may also include a sampler 122. Before a gas or fluid to be analyzed (referred to herein as a “formation fluid”) can be introduced into the gas chromatography apparatus 100a, a sample of the formation fluid may be extracted from its environment (e.g., from a rock formation in the case of boreholes). Thus, a self-contained gas chromatography system 100a may include the sampler 122 to perform this extraction/sampling. In downhole environments, the formation fluid may be at high pressure (e.g., about 20 Kpsi) and high temperature (up to about 200° C. or even higher). Traditional chromatographic methods require that the sample be de-pressurized, while carefully modulating its temperature to control the separation process. According to one embodiment, a micro-scale sampler 122 can optionally be integrated into the gas chromatography apparatus 100a. The sampler 122 may be coupled to a heater 124 to achieve at least some temperature modulation. In one example, the sampler 122 may be a multi-stage sampler and phase separator. In this example, the sampler 122 may perform phase separation to eliminate water, which can deteriorate gas chromatographic analysis. Being at the micro-scale, the sampler 122 may then isolate a minute quantity of formation fluid, for example, in the sub-micro liter or nano-liter range. Depressurization may be accomplished in an expansion chamber accompanied by appropriate temperature control to preserve the sample elution. The GC system 100a may comprise other components known in the art such as are shown in U.S. Published Patent Application 2008/0121017.

A chromatograph generally benefits from precise control and manipulation of the temperature of its major components. As discussed above, in chromatography, separations occur as a sample moves through the column and the time taken for components of the sample to exit the column depends on their affinity to the stationary phase. This affinity has a strong dependence on temperature and therefore, the temperature of the column may need to be very accurately controlled. Some components separate more effectively at low temperatures, whereas other components separate more effectively at high temperatures. Therefore, the temperature of the separation column may need to be controlled to temperatures below the ambient environmental temperature, particularly for downhole operation where the ambient temperature may be 200° C. or higher. Accordingly, a cooling device may be needed to maintain a desired temperature of the separation column. In addition, some analyses may involve heating the separation column with a fast and well-defined increasing temperature ramp. After a sample analysis is completed, the separation column may be cooled to the lower starting temperature. Thus, in some examples, the separation column may need to be heated and cooled cyclically for each analysis. The rate of heating may need to be fast for certain applications, while the rate of cooling preferably may be as fast as possible to minimize lag time between successive analyses. The cooling process can be particularly time consuming unless a cooling mechanism, such as a fan or other cooling device, is provided. However, both the heating apparatus and the cooling apparatus may contribute to the total thermal mass of the GC device. In general, increasing the thermal mass may make the heating, and particularly the cooling, functions slow and inefficient.

In addition to controlling the temperature of the separation column, the temperatures of other components, for example, the injector and/or the detector may also need to be controlled. Furthermore, different components may need to be maintained at different operating temperatures from one another. For example, some analyses may require temperature ramping of the separation column while holding the injector and detector at a constant temperature. Also, the temperature distribution throughout the separation column, including its inlet and outlet, may preferably be uniform to maintain the quality of chromatographic separation. In many circumstances, the injector and the detector, as well as the fluidic interconnections, may also preferably need to be held at a controlled temperature to avoid cold spots and uneven thermal distribution. In conventional large-scale gas chromatography systems, thermal management is challenging and may be particularly difficult at high ambient temperatures. Traditional heating and cooling devices may have high thermal mass, adding to the complexity of the thermal management. In addition, even “miniaturized” fluidic connections used in traditional gas chromatography apparatus have large enough thermal mass, that thermal management becomes difficult at best. This is particularly the case in a downhole environment where tool space is limited and it is difficult to eject heat from components and cooling apparatus due to the high ambient temperature. Accordingly, using a traditional approach to heating and/or cooling in a downhole tool can result in excessively long analyses times (due to slow, inefficient cooling) along with a complex and inefficient thermal management apparatus.

As discussed above, a particular GC component that may require or benefit from precisely controlled, flexible thermal management is the gas chromatography column. For example, as discussed herein, for some analyses, the column may be provided with a fast temperature ramp and/or may be quickly cooled between analyses to speed up data acquisition time. As discussed herein, a preferred GC column according to the invention is a MEMS device that includes a substrate such as a silicon substrate with a contiguous channel fabricated therein and coated with a carbon nanotube stationary phase for chromatographic analysis. To achieve thermal management, the column may include integrated heating and/or cooling devices as discussed above. These devices may control the temperature of the column independent of the surrounding temperature of the overall chromatography system and other GC components within the system.

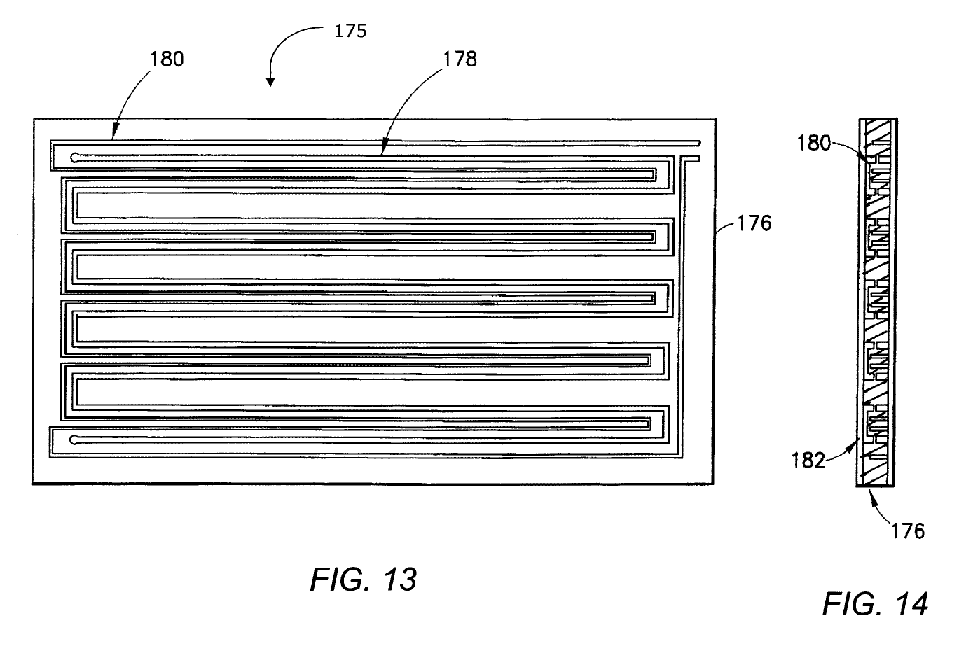

Referring to FIG. 13, there is illustrated a top view of one example of a geometry for a micro-scale GC column 175 of the invention as implemented as a microchip and including embedded heating and optional cooling. In the illustrated embodiment, the micro-column 175 includes a substrate 176 such as any substrate described elsewhere herein. A contiguous column channel 178 is fabricated in the substrate 176, for example, by etching or micro-machining, or as other methods described herein or known in the art and provides the flow pathway for the sample through the column 175. The channel 178 has deposited thereon a CNT stationary phase as previously discussed herein. Ports may couple the column channel 178 to, for example, a micro-fluidic platform (as described earlier) or to another GC component (e.g., a detector or second column). A second contiguous channel 180 may be fabricated in the substrate 176 interleaved with the column channel 178, as shown in FIG. 13. This channel 180 may contain a heating element (not shown). For example, the heating element may be a resistive wire (e.g., a metallic conductor coated with a dielectric insulator) that is laid inside the channel 180. Alternatively, a conductive (e.g., metallic) layer may be deposited on the channel 180 as well as optionally on other surfaces of the microchip. The heating element (e.g., conductive layer or resistive wire) may be coupled to the power supply 126 (see FIG. 10) such that the heating element may be electrically heated to heat the column.

Further, in a particular embodiment, the catalytic metallic coating which is sputtered on the inner walls of the channels of the separation columns described herein (e.g., catalyst layer 66 of FIG. 3D) may be coupled to the power supply such that the catalytic metallic coating can serve as a heating element for heating the stationary phase material (e.g., the CNT mat 70 of FIG. 3E) within the separation column.

In another embodiment, a contiguous cooling channel 182 may be provided on the microchip (FIG. 14). In one embodiment, a cooling fluid may be provided in the cooling channel 182. It is to be appreciated that the representative geometries shown in FIGS. 13 and 14 are for illustration only and are not intended to be limiting. Various other geometries are envisioned and may be apparent to those skilled in the art. For example, the cooling channel 182 may be provided on the same side of the microchip as the column channel 180. In another example, the heating channel 180 may be provided on the reverse side of the microchip. In another example, either or both of the heating and cooling channels 180 and 182 may comprise a plurality of channels, rather than a single contiguous channel. These and other modifications to the geometry that may be apparent to those skilled in the art are intended to be part of this disclosure. Furthermore, although not shown in FIGS. 13 and 14, the GC column may be provided with an optional low thermal mass heating device, such as a thermoelectric heating device as discussed above, in addition to the heating channel 180. In one example, such a heating device may include a low thermal mass thin-film Peltier device that may be attached to one or both sides of the microchip. The thin-film Peltier device may be approximately the same size as the microchip and may be used to provide heating and/or cooling to achieve a desired ambient or in the case of a ramped system, a desired starting temperature for the GC column, as discussed above. Embodiments of the micro-column thus may integrate a heater, an optional flow path for a cooling fluid, and a GC separation column in a MEMS device having very low thermal mass.

Alternatively, rather than supplying a coolant in the cooling channel(s) 182, cooling may be achieved using air convection. The heat from the column may be transported through the silicon and/or glass substrate to the chip surfaces, then carried away by air convection. For cooling by convection, cooling channels 182 may not be necessary; however, cooling channels 182 may increase the surface area of the microchip, thereby allowing for more efficient convective cooling.

Having now described some illustrative embodiments of the invention, it should be apparent to those skilled in the art that the foregoing is merely illustrative and not limiting, having been presented by way of example for the purposes of clarity. Numerous modifications and other embodiments are within the scope of one of ordinary skill in the art and are contemplated as falling within the scope of the invention. In particular, although many of the examples presented herein involve specific combinations of method acts or system elements, it should be understood that those acts and those elements may be combined in other ways to accomplish the same objectives. For example, the chromatographic systems and techniques of the invention can be implemented to analyze components other than natural gas in a variety of environments including but not limited to downhole environments.

Further, those skilled in the art should appreciate that the parameters and configurations described herein are exemplary and that actual parameters and/or configurations will depend on the specific application in which the systems and techniques of the invention are used. Those skilled in the art should also recognize or be able to ascertain, using no more than routine experimentation, equivalents to the specific embodiments of the invention. It is therefore to be understood that the embodiments described herein are presented by way of example only and that, within the scope of the appended claims and equivalents thereto; the invention may be practiced otherwise than as specifically described.

Moreover, it should also be appreciated that the invention is directed to each feature, system, subsystem, or technique described herein and any combination of two or more features, systems, subsystems, or techniques described herein and any combination of two or more features, systems, subsystems, and/or methods, if such features, systems, subsystems, and techniques are not mutually inconsistent, is considered to be within the scope of the invention as embodied in the claims. Further, acts, elements, and features discussed only in connection with one embodiment are not intended to be excluded from a similar role in other embodiments. Rather, the systems and methods of the present disclosure are susceptible to various modifications, variations and/or enhancements without departing from the spirit or scope of the present disclosure. Accordingly, the present disclosure expressly encompasses all such modifications, variations and enhancements within its scope.

What is claimed is:

1. A method for micro-fabricating a carbon nanostructured gas chromatography channel, comprising the steps of:
providing a substrate;
preparing and etching a surface of the substrate to form an etched substrate having a fluid channel;
assembling a mat of carbon nanotubes on a wall surface of the fluid channel, wherein the mat of carbon nanotubes is substantially uniform in thickness along the length of the fluid channel, and the formation of contaminates on the surface of the etched substrate is minimized; and
disposing a cover over at least a portion of the surface of the etched substrate for enclosing at least a portion of the fluid channel.

2. The method of claim 1, wherein the step of preparing and etching further comprises:
applying a photoresist material upon the surface of the substrate;
removing a portion of the photoresist material using photolithography; and
etching the fluid channel in the substrate using a deep reactive ion etching process.

3. The method of claim 1 wherein the step of assembling the mat of carbon nanotubes comprises:
exposing the etched substrate to a metal or metal precursor to form a metal catalyst layer thereon, wherein at least a portion of the metal catalyst layer is formed upon the wall surface of the fluid channel; and
exposing the metal catalyst layer to a carbon-containing gas at a temperature suitable for formation of carbon nanotubes on the wall surface of the fluid channel.

4. The method of claim 3, wherein in the step of exposing the etched substrate to a metal or metal precursor to form the metal catalyst layer thereon, the metal or metal precursor comprises at least one of a Group VIII, Group Vb, Group VIb, Group VII, or lanthanide metal, or an alloy comprising an additional metal.

5. The method of claim 1 wherein the substrate comprises silicon, glass, sapphire, gallium arsenide, and/or a Group III-IV material, and which is doped or undoped.

6. The method of claim 1 wherein the carbon nanotubes comprise single-walled carbon nanotubes and/or multi-walled carbon nanotubes.

7. The method of claim 1 wherein at least a portion of the fluid channel is enclosed using a Pyrex glass wafer and/or silicon.

8. The method of claim 1 wherein the step of assembling the carbon nanotubes occurs in a manner to reduce formation of amorphous carbon on the surface of the etched substrate.

9. A micro-scale gas chromatograph for separating components of natural gas, comprising:
an injector block for providing a gas sample for separation into a plurality of components;
a separation column for receiving the gas sample, the separation column having an input to receive the gas sample, a stationary phase comprised of carbon nanotubes grown upon a metal catalytic layer disposed upon a micro-channel in the separation column in a substantially uniform layer along the length of the micro-channel, and an output through which is expelled the components of the gas sample; and
a detector arranged to receive the components of the gas sample from the output of the separation column.

10. The micro-scale gas chromatograph of claim 9 wherein the separation column is etched into a silicon-based substrate.

11. The micro-scale gas chromatograph of claim 9 wherein the separation column has a micro-channel length of at least 0.5 m.

12. The micro-scale gas chromatograph of claim 9 which is adapted for use on-site at or near a wellhead of a wellbore.

13. A method for analyzing a gas sample comprising a plurality of analytes having molecular masses lower than hexane, comprising the steps of:
providing the micro-scale gas chromatograph of claim 9;
injecting the gas sample into the micro-scale gas chromatograph wherein at least a portion of the plurality of analytes are separated by the carbon nanotubes in the separation column of the micro-scale gas chromatograph; and
detecting the portion of the plurality of analytes separated by the separation column as a function of time.

14. The method of claim 13 wherein the portion of the plurality of analytes separated by the separation column comprises at least two of methane, ethane, a propane, a butane, a pentane, carbon dioxide, oxygen, nitrogen and hydrogen sulfide.

15. The method of claim 13 wherein the gas sample is analyzed at surface by positioning the micro-scale gas chromatograph in fluid communication with a sampling apparatus and/or a separator apparatus wherein the gas sample is obtained from a fluid formation adjacent a wellbore.

16. The method of claim 13 wherein the gas sample is analyzed downhole by disposing the micro-scale gas chromatograph within a wellbore and the gas sample is obtained from a fluid formation adjacent the wellbore.

17. The method of claim 13 wherein the analytes separated in the separation column are separated by a resolution factor R>1.5.

18. The method of claim 13 wherein the carbon nanotubes of the separation column are heated by passing an electric current through the metal catalyst layer of the micro-scale gas chromatograph.

19. A downhole tool for analyzing a fluid sample in a wellbore, the downhole tool comprising:
a housing operatively connected to a conveyable line;
the micro-scale gas chromatograph of claim 9 positioned in the housing; and
a communication link providing an operative communication between the micro-scale gas chromatograph of the downhole tool and a power assembly.

20. The downhole tool of claim 19 which comprises a drilling tool, a wireline tool, a tool string, a bottom hole assembly, or a well survey apparatus.
